(19) United States
(12) Patent Application Publication
(10) Pub. No.: US 2009/0261148 A1
(43) Pub. Date: Oct. 22, 2009

(54) PRODUCTION METHOD OF SOLDER CIRCUIT BOARD

(75) Inventors: Takashi Shoji, Tokyo (JP); Takekazu Sakai, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., TOKYO (JP)

(21) Appl. No.: 12/375,341

(22) PCT Filed: Jul. 27, 2007
(86) PCT No.: PCT/JP2007/065217

§ 371 Date: Feb. 24, 2009

(30) Foreign Application Priority Data
Aug. 3, 2006 (JP) 2006-211860
Aug. 4, 2006 (JP) 2006-213061

(51) Int. Cl. B23K 1/20

(52) U.S. Cl. 228/203

(57) ABSTRACT

A method for producing a solder circuit board includes the steps of imparting tackiness to a surface of an electrically conductive circuit electrode on a printed-wiring board to form a tacky part, causing only one solder particle to adhere to the tacky part, and heating the printed-wiring board, thereby melting the solder particle to form a bump part which corresponds to the tacky part and to which an electronic part is to be connected and forming a solder circuit.

### CROSS REFERENCE TO RELATED APPLICATIONS

This application is an application filed under 35 U.S.C. §111(a) claiming the benefit pursuant to 35 U.S.C. §119(e)(1) of the filing dates of Japanese Patent Applications No. 2006-211860 filed Aug. 3, 2006 and No. 2006-213061 filed Aug. 4, 2006 pursuant to 35 U.S.C. §111(b).

### TECHNICAL FIELD

This invention relates to a method for producing a solder circuit board using a solder particle of specific shape and size and more particularly to a method for forming a connecting bump to be used for joining an LSI chip of a structure, such as a ball grid array (BGA) structure, onto a solder circuit board and a method for forming a connecting bump to be disposed on the LSI chip.

### BACKGROUND ART

In recent years, there have been developed printed wiring boards, in which a circuit pattern is formed on an insulating substrate, such as a plastic substrate, a ceramic substrate or a metallic substrate having thereon a coating layer formed from plastic or the like. Formation of an electronic circuit from such a printed wiring board typically employs a technique of soldering electronic parts, such as IC elements, semiconductor chips, resistors and capacitors, onto the circuit pattern.

When such a technique is employed, the process for joining a lead terminal of an electronic part to a predetermined area of the circuit pattern typically proceeds as follows: forming in advance a solder thin layer on the surface of a conductive circuit electrode provided on the substrate; applying a solder paste or a flux through printing; positioning and placing an electronic part of interest and reflowing the solder thin layer or both the solder thin layer and the solder paste.

In a recent trend for the miniaturization of electronic products, demand has arisen for fine-pitch patterning of solder circuit boards. On such solder circuit boards, fine-pitch parts, such as a 0.3-mm-pitch QFP (Quad Flat Package) LSI and CSP (Chip Size Package) and a 0.15-mm-pitch FC (Flip Chip) are mounted. In order to mount such a chip on the solder circuit board, a solder bump formed on the chip and a solder bump formed on the solder circuit board are overlaid one on top of the other, and the bumps are reflowed to join the chip and the solder circuit board together. For this reason, the solder circuit board is required to form thereon a protuberant electrode part that is a so-called a bump for electric part connection. The electrode part is required to have a fine pattern in compliance with a fine pitch of the chip.

When a bump for connection is formed on a printed wiring board by means of soldering, a method, such as plating, the hot air leveler (HAL) method or a combination of printing solder powder paste and reflowing is employed. However, plating has a drawback in that a thick solder layer is difficult to form, and the HAL method and printing of solder paste encounter difficulty in provision of fine-pitch patterns.

In order to overcome the aforementioned drawbacks, a method for forming a solder circuit without requiring cumbersome operations, such as positioning of a circuit pattern, is disclosed (see, for example, JP-A HEI 7-7244). In the method, the surface of a conductive circuit electrode provided on a printed wiring board is reacted with a tackiness-imparting compound so as to impart tackiness to the surface, solder powder is deposited on the thus formed tacky area, and the printed wiring board is heated so as to melt the solder, whereby a solder circuit is formed.

Employment of the method disclosed in JP-A HEI 7-7244 enables a minute solder circuit pattern to be formed through a simple operation, thereby providing a circuit board with high reliability. However, since the solder powder used in the prior art method preferably has sharp particle size distribution, it is very expensive. In addition, the prior art method has posed the problems in that plural solder powders adhere to the tacky area on which a bump for the solder circuit board is to be formed to make the height of the solder bump inhomogeneous and that the solder powder fails to adhere to a relevant place to form an incomplete solder bump. Furthermore, when using an ordinary spherical solder powder, since the portion of contact between the circuit board to which tackiness has been imparted and the solder powder assumes a dotted shape, there has been a possibility of the solder powder dropping off the circuit board. Moreover, since the thickness of a solder layer on the formed circuit board has to be controlled only by means of the particle diameter of the solder powder, the thickness of the solder layer has been difficult to control.

This invention, perfected with a view to solving these problems and specifically providing a method for producing a solder circuit board using a solder particle processed to a specific shape agreeable to the method for producing a solder circuit board disclosed in JP-A HEI 7-7244, is directed to providing a method for producing a solder circuit board excelling in economy, a method for producing a solder circuit board capable of realizing a circuit pattern abounding with fineness and processing accuracy, a solder circuit board possessing a circuit board abounding with fineness and processing accuracy, scarcely entailing dispersion of solder layer thickness, and excelling in reliability, and an electronic circuit part provided with an electronic part capable of realizing high reliability and high packaging density.

The present inventors have carried out extensive studies in order to solve the aforementioned problems, and have achieved the present invention. Accordingly, the present inventors have developed the following techniques through which the problems have been solved.

### DISCLOSURE OF THE INVENTION

The present invention provides as the first aspect thereof a method for producing a solder circuit board, comprising the steps of imparting tackiness to a surface of an electrically conductive circuit electrode on a printed-wiring board to form a tacky part, causing only one solder particle to adhere to the tacky part, and heating the printed-wiring board, thereby melting the solder particle to form a bump part which corresponds to the tacky part and to which an electronic part is to be connected and forming a solder circuit.

The present invention further provides as the second aspect thereof a method for producing a solder circuit board, comprising the steps of coating part of an electrically conductive circuit electrode on a printed-wiring board with resist so as to form an opening therein, imparting tackiness to the opening to form a tacky part, causing only one solder particle to adhere to the tacky part, and heating the printed-wiring board, thereby melting the solder particle and forming a solder circuit.

In the third aspect of the invention directed to the method according to the second aspect, the solder particle is spherical, the opening is circular and, when the opening has a diameter of D1, the solder particle has a diameter of D2 and the resist has a thickness of D3, satisfied is 1>(D1−2×((D2−D3)×D3)^{1/2})/D2≧0.

In the fourth aspect of the invention directed to the method according to the first or second aspect, the solder particle is obtained by punching a solder sheet out.

In the fifth aspect of the invention directed to the method according to the fourth aspect, the solder particle has an average width in a range of 30 to 90% of a size of the opening.

In the sixth aspect of the invention directed to the method according to the fourth or fifth aspect, the solder sheet has an average thickness in a range of 100 to 300% of a thickness of the solder circuit to be formed.

In the seventh aspect of the invention directed to the method according to the first or second aspect, the solder particle is a rod of a prescribed length cut from wire solder.

In the eighth aspect of the invention directed to the method according to the seventh aspect, the wire solder has a thickness in a range of 50 to 90% of a size of the opening.

In the ninth aspect of the invention directed to the method according to any one of the first to eighth aspects, the step of causing the solder particle to adhere to the tacky part comprises dispersing the solder particle in a liquid and immersing the printed-circuit board in the liquid.

In the tenth aspect of the invention directed to the method according to the ninth aspect, the liquid is a deoxidized liquid.

In the eleventh aspect of the invention directed to the method according to any one of the first to eighth aspects, the solder particle is caused to adhere to the tacky part by means of vibration in an ambient air or by use of an adsorbing jig or mounter.

By the method of this invention for producing a solder circuit board, it is rendered possible to form a fine solder circuit pattern with small dispersion of solder layer thickness by a simple procedure and as well eliminate deficiency of a solder bump. Further, concerning the solder of an alloy composition that has heretofore incurred difficulty in producing a particle of a specific size, this method enables producing solder particles uniform in shape and size conveniently. Particularly, in a fine circuit pattern, this method brings about the effect of decreasing short circuits with solder metal between the adjacent circuit patterns and uniformizing the thickness of the solder layer of the circuit pattern and markedly enhances the reliability of a solder circuit board. By the method of this invention for producing a solder circuit board, it becomes possible to realize miniaturization of a circuit board having an electronic part mounted thereon and impartation of high reliability thereto and consequently provide an electronic device of excellent special quality.

Besides, the present invention brings about the effect of solving the following problems (1) to (4) which would possibly occur in using a solder powder obtained by punching with a punch.

(1) The method that comprises mounting one relatively large particle on a circuit and fusing it with superheat has suffered use of very expensive powder for the purpose of preparing the particle by fusing a solder resulting from augmenting processing precision.

(2) The conventional technique has necessitated the particle to possess very high sphericity because the particle of very high precision produced in the preceding item (1), when used for the formation of the circuit, is attracted by an aspirating jig.

(3) Since the aspirating jig must be identical in shape with the circuit, it has to be prepared anew each time the circuit is changed.

(4) On account of the use of the aspirating jig, the work involved has to be carried out in a room of extremely high degree of cleanliness with a view to preventing foreign particles from being drawn in through an air intake.

This invention enables coping with fineness of pitch of 200 μm or less that has never been satisfied by the conventional printing technique. Consequently, it has become feasible to provide a solder circuit that befits CSP, area array type flip chip and ball grid array (BGA).

### BEST MODE FOR CARRYING OUT THE INVENTION

The printed-wiring board that is contemplated by this invention embraces one-side printed-wiring board, double-side printed-wiring board, multilayer printed-wiring board and flexible printed-wiring board that result from forming a circuit pattern of an electrically conductive substance, such as metal, on a plastic substrate, plastic film substrate, glass fabric substrate, paper-based epoxy resin substrate, substrate obtained by depositing a metal plate on a ceramic substrate or insulated substrate obtained by coating a metallic substrate with plastic or ceramic. It can be applied to an IC substrate, capacitor, resistor, coil, varistor, bare chip and wafer, for example.

This invention is characterized by particularly being provided on a printed-wiring board with a connecting bump for allowing connection of an LSI chip of BGA structure, for example.

The present invention implements the formation of a connecting bump for an electronic part by imparting tackiness to the surface of an electrically conductive circuit electrode on a printed-wiring board to form a tacky part, attaching a solder particle to the tacky part and heating the printed-wiring board, thereby melting the solder particle and forming a solder circuit.

The present invention is characterized by attaching just one solder particle to the connecting bump part of an electronic part endowed in advance with tackiness. It is further characterized by covering the electrically conductive circuit electrode part with resist in such a manner that an opening may be formed in part of the electrically conductive circuit electrode part, imparting tackiness to the opening and thereafter attaching just one solder particle to the resultant tacky opening. This invention, in this while, is characterized by covering the periphery of the circuit electrode part requiring attachment of a solder particle for the formation of a bump in advance with resist, thereby giving such a circular shape to the opening that the relation of the formula shown herein below may exist among D1, D2 and D3, wherein D1 denotes the diameter of the circular opening, D2 denotes the diameter of the solder particle and D3 denotes the thickness of the resist on the circuit electrode part.

1>(D1−2×((D2−D3)×D3)^{1/2})/D2≧0

By producing the printed-circuit board using the method described above, it is rendered possible to define the height of the solder bump for connecting the electronic part relative to the surface of the circuit board and ensure production of the printed-circuit board free from any fracture of the solder bump for connecting the electronic part.

By causing these terms D1, D2 and D3 to satisfy the relation of the formula shown herein below, it is made possible to attach just one solder particle to the connecting solder bump part.

0.9≧(D1−2×((D2−D3)×D3)^{1/2})/D2≧0.05

Furthermore, this invention, in respect to a method for producing a solder particle for use in forming a circuit of an electronic circuit board, contemplates punching a solder particle out of a solder sheet alloy with a punch and using the solder particle or, in respect to solder to be used for forming a circuit of an electronic circuit board, contemplates producing a solder particle by cutting a definite length of wire solder alloy, attaching the definite length of solder to a tacky part of the circuit and fusing the solder per se, thereby producing a solder-circuit board.

As examples of the metallic composition of the solder particle to be used for producing the solder particle of this invention, Sn—Pb-based, Sn—Pb—Ag-based, Sn—Pb—Bi-based, Sn—Pb—Bi—Ag-based and Sn—Pb—Cd-based compositions may be cited. From the recent viewpoint of excluding Pb from the industrial waste, it is preferable to use Pb-free compositions, such as Sn—In-based, Sn—Bi-based, In—Ag-based, In—Bi-based, Sn—Zn-based, Sn—Ag-based, Sn—Cu-based, Sn—Sb-based, Sn—Au-based, Sn—Bi—Ag—Cu-based, Sn—Ge-based, Sn—Bi—Cu-based, Sn—Cu—Sb—Ag-based, Sn—Ag—Zn-based, Sn—Cu—Ag-based, Sn—Bi—Sb-based, Sn—Bi—Sb—Zn-based, Sn—Bi—Cu—Zn-based, Sn—Ag—Sb-based, Sn—Ag—Sb—Zn-based, Sn—Ag—Cu—Zn-based and Sn—Zn—Bi-based compositions.

As concrete examples of the aforementioned compositions, the eutectic solder composed of 63 mass % of Sn and 37 mass % of Pb (hereinafter expressed as “63Sn-37P”) and playing a central role, and 62Sn-36Pb-2Ag, 62.6Sn-37Pb-0.4Ag, 60Sn-40Pb, 50Sn-50Pb, 30Sn-70Pb, 25Sn-75Pb, 10Sn-88Pb-2Ag, 46Sn-8Bi-46Pb, 57Sn-3Bi-40Pb, 42Sn-42Pb-14Bi-2Ag, 45Sn-40Pb-15Bi, 50Sn-32Pb-18Cd, 48Sn-52In, 43Sn-57Bi, 97In-3Ag, 58Sn-42In, 95In-5Bi, 60Sn-40Bi 91Sn-9Zn, 96.5Sn-3.5Ag, 99.3Sn-0.7Cu, 95Sn-5Sb, 20Sn-80Au, 90Sn-10Ag, 90Sn-7.5Bi-2Ag-0.5Cu, 97Sn-3Cu, 99Sn-1Ge, 92Sn-7.5Bi-0.5Cu, 97Sn-2Cu-0.8Sb-0.2Ag, 95.5Sn-3.5Ag-1Zn, 95.5Sn-4Cu-0.5Ag, 52Sn-45Bi-3Sb, 51Sn-45Bi-3Sb-1Zn, 85Sn-10Bi-5Sb, 84Sn-10Bi-5Sb-1Zn, 88.2Sn-10Bi-0.8Cu-1Zn, 89Sn-4Ag-7Sb, 88Sn-4Ag-7Sb-1Zn, 98Sn-1Ag-1Sb, 97Sn-1Ag-1Sb-1Zn, 91.2Sn-2Ag-0.8Cu-6Zn, 89Sn-8Zn-3Bi, 86Sn-8Zn-6Bi, and 89.1 Sn-2Ag-0.9Cu-8Zn may be cited.

Generally, the atomizing method is adopted for the production of a solder powder. The term “atomizing method” refers to a method that prepares a powder by spraying a molten solder alloy in the form of mist and solidifying the mist in the space of an inert gas atmosphere. The solder powder prepared by this method tends to have the surface thereof oxidized with the trace of oxygen contained in the solidifying atmosphere. Particularly, the lead-free solder containing Ag or Zn has suffered the reflow characteristics to be deteriorated owing to the influence of the oxide film formed on the surface of the powder. Many alloys incur difficulty in producing a powder by the atomizing method.

Heretofore, since the solder alloy generally uses the atomizing (spraying) method for particle size reduction, it produces particles of sizes varied over a wide range. Though it is subsequently required that these particles be classified by sieving, the sieving incurs difficulty in completely removing fine particles. The fine particles that escape removal by sieving occasionally exert an adverse effect inevitably on the circuit board.

With a view to a precise and fine circuit, the powder of extremely high sphericity resulting from melting a solder sheet or wire that is easy to produce is used as the raw material for the production of a solder particle. Thus, the powder thus used is extremely expensive.

This invention enables obviating the necessity for using this expensive powder by implementing the process for cutting the solder sheet or wire into small particles at room temperature. Further, the avoidance of using the atomizing method has resulted in widening the scope of alloys that are usable as the solder powder of uniform sphericity.

This invention enables the production of the solder particles by punching them out of a solder sheet by the use of a punch. The shape of this punching may be freely selected from among square, rectangle, polygon, circle, ellipse, for example. From among other shapes enumerated above, the circular shape proves particularly preferable in relation to the shape of a resist opening. The thickness of the sheet remains as it is to be the thickness of the solder particle to be produced and this thickness can be freely selected to suit the thickness of the solder particle expected to be produced.

The solder particle contemplated by this invention can be produced by cutting a solder wire in a definite length as with a cutter. The thickness and length of the wire particle expected to be cut may be freely selected to suit the size of the solder particle required to be produced (corresponding to the size of the connecting bump part and the resist opening).

This invention concerns a method for producing a solder-circuit board, for example, by coating the surface of an electrically conductive circuit electrode on the electronic circuit substrate or the circuit substrate with resist, causing the surface of the electrode of the electrically conductive circuit board exposed by opening the part corresponding to the electrode to react with a tackiness-imparting compound, thereby imparting tackiness thereto, attaching just one solder particle to the connecting solder bump part of the resultant tacky part and heating the electronic circuit board, thereby fusing the solder particle and forming a solder circuit.

This invention forms the opening in a circular shape by causing the periphery of the circuit electrode part fated to seat the solder bump to be coated with resist. The circular shape prefers to be a perfect circle but may be substituted with an ellipse or a square. When the opening has a shape other than a perfect circle, the state of attachment of the solder particle similar to that obtained of a perfect circle will be realized by assuming the size D1 to be the diameter of the inscribed circle of the pertinent shape.

The resist to be used in this invention is an insulating resist generally used in the production of an electronic circuit board. It is a resist such in nature that it will avoid exhibiting tackiness during the course of imparting tackiness to the surface of an electrically conductive circuit electrode on a printed-wiring board, which will be described hereinafter.

This invention prefers to give a treatment with the solution of a tackiness-imparting compound to the part other than the part for forming a solder bump while the electrically conductive circuit part requiring no coating with a solider is coated with resist.

Though copper is used in almost all cases as the electrically conductive substance to form the electrically conductive circuit electrode of an electronic circuit substrate, this invention does not need to limit the substance to copper but allows it to be an electrically conductive substance that is enabled to acquire tackiness on the surface thereof by a tackiness-imparting substance which will be described hereinafter. The substance for use in the circuit may contain Ni, Sn, Ni—Au or solder alloy, for example.

The tackiness-imparting compounds that are preferably used in this invention include naphthotriazole-based derivatives, benzotriazole-based derivatives, imidazole-based derivatives, benzoimidazole-based derivatives, mercaptobenzothiazole-based derivatives and benzothiazole thiofatty acids may be cited. While these tackiness-imparting compounds exhibit strong effects particularly on copper, they are capable of imparting tackiness to other electrically conductive substances as well.

In this invention, the benzotriazole-based derivatives are represented by the following general formula (1):

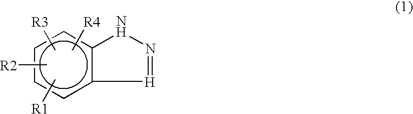

(wherein R1 to R4 independently denote a hydrogen atom, an alkyl group of 1 to 16, preferably 5 to 16, carbon atoms, an alkoxy group, F, Br, Cl, I, a cyano group, an amino group or an OH group).

The naphthotriazole-based derivatives are represented by the general formula (2):

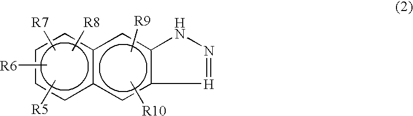

(wherein R5 to R10 independently denote a hydrogen atom, an alkyl group of 1 to 16, preferably 5 to 16, carbon atoms, an alkoxy group, F, Br, Cl, I, a cyano group, an amino group or an OH group).

The imidazole-based derivatives are represented by the general formula (3):

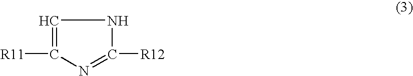

(wherein R11 and R12 independently denote a hydrogen atom, an alkyl group of 1 to 16, preferably 5 to 16, carbon atoms, an alkoxy group, F, Br, Cl, I, a cyano group, an amino group or an OH group).

The benzoimidazole-based derivatives are represented by the general formula (4):

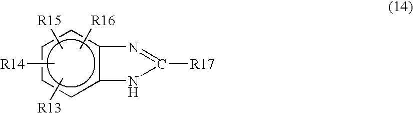

(wherein R13 to R17 independently denote a hydrogen atom, an alkyl group of 1 to 16, preferably 5 to 16, carbon atoms, an alkoxy group, F, Br, Cl, I, a cyano group, an amino group or an OH group).

The mercaptobenzothiazole-based derivatives are represented by the general formula (5):

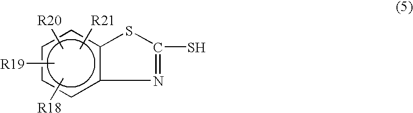

(wherein R18 to R21 independently denote a hydrogen atom, an alkyl group of 1 to 16, preferably 5 to 16, carbon atoms, an alkoxy group, F, Br, Cl, I, a cyano group, an amino group or an OH group).

The benzothiazole thiofatty acid-based derivatives are represented by the general formula (6):

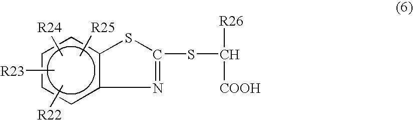

(wherein R22 to R26 independently denote a hydrogen atom, an alkyl group of 1 to 16, preferably 1 or 2, carbon atoms, an alkoxy group, F, Br, Cl, I, a cyano group, an amino group or an OH group).

Of these compounds, the benzotriazole-based derivatives represented by the general formula (1) generally gain in tackiness in accordance as the number of carbon atoms of R1 to R4 increases.

Likewise, the imidazole-based derivatives and the benzoimidazole-based derivatives represented respectively by the general formulae (3) and (4) generally gain in tackiness in accordance as the number of carbon atoms of R11 to R17 increases.

In the benzothiazole thiofatty acid-based derivatives represented by the general formula (6), the number of carbon atoms of each of R22 to R26 is preferred to be 1 or 2.

In this invention, at least one of the tackiness-imparting compounds is dissolved in water or an acid water and preferably used as adjusted to slight acidity of the degree of pH 3 to 5. As the substances to be used for the adjustment of pH, inorganic acids, such as hydrochloric acid, sulfuric acid, nitric acid and phosphoric acid, may be cited where the electrically conductive substance happens to be a metal. As organic acids, formic acid, acetic acid, propionic acid, malic acid, oxalic acid, malonic acid, succinic acid, tartaric acid, etc. are usable. The concentrations of the tackiness-imparting compounds do not need to be rigidly limited but may be properly adjusted to suit solubility and condition of use. Preferably, the concentrations in the range of 0.05 mass % to 20 mass % allow ready use as a whole. If the concentration falls short of the range, the shortage will prove to be unfavorable in performance on account of insufficient formation of the tacky film.

The treating temperature, when raised slightly above room temperature, proves favorable in terms of the speed and the amount of formation of the tacky film. It is not definite, for it is variable with the concentration of the tackiness-imparting compound, the kind of metal, etc. Generally, however, it preferably falls in the range of 30° C. to 60° C. Though the immersing time is not definitive, it is preferable to adjust the other conditions so that the immersing time may fall in the approximate range of 5 sec to 60 min from the viewpoint of working efficiency.

Incidentally in this case, the presence of copper as ions in an amount of 100 to 1000 ppm in the solution is at an advantage in heightening the efficiency of formation like the speed and the amount of formation of the tacky film.

The electronic circuit board to be treated is prepared in a state such that the electrically conductive circuit board requiring no solder may be kept coated with resist, for example, and the part of the circuit pattern may be sporadically kept exposed and treated with a tackiness-imparting compound solution.

The treatment with the tackiness-imparting compound solution is implemented by either causing the electronic circuit board about to form a solder circuit to be immersed in the tackiness-imparting compound solution or applying the tackiness-imparting compound solution thereto. This treatment results in imparting tackiness to the exposed surface of the electrode of the electrically conductive circuit board.

This invention prefers to attach a spherical solder particle or a solder particle processed to a definite shape to the surface of the electrode of the electrically conductive circuit board that has undergone the impartation of tackiness by placing the solder particle produced by the method described above in a solder particle-attaching device, mounting the electronic circuit board in the device, and tilting the container of the solder particle, thereby allowing the solder particle to adhere to the connecting solder bump part endowed in advance with tackiness. The solder particle, when placed in the solder particle-attaching device, can be prevented from being scattered and the solder particle, when the solder particle-attaching device is tilted, can be attached as expected. The solder particle, once it is attached fast in consequence of addition to the area of attachment, will be scarcely detached but can be kept stably in position.

The solder metal can be generally processed easily into a thin wire because it excels in flatting property. The wire to be used for producing the solder particle of this invention, therefore, can be easily produced.

For the treatment directed to attaching a solder particle, use of a spherical solder particle has heretofore occurred more often than not. By using, as in this invention, a solder particle of a flat shape punched out of a sheet solder foil with a punch or a solder particle cut in a definite length out of a wire solder line, however, it is rendered possible to add to the area of contact between the tacky part and the solder particle and attain stable attachment of the solder particle. Since the solder particles so obtained by this invention have a very sharp particle size distribution, they are enabled to produce solder circuit boards of high precision more stably than the conventional method that uses solder powder.

This invention enables the size of the solder particle to be freely controlled by the thickness of the solder sheet, the size of the punch used for perforation, the thickness of the solder wire or the length in which the wire is cut off. The solder particle punched out with the punch, when the average width thereof is fixed within the range of 30 to 90%, preferably 40 to 80% and more preferably 50 to 75%, of the width of the electrode part fated to require impartation of tackiness, enables stabilizing the adhesion of the solder particle and as well uniformizing the thickness of the solder layer in the circuit part after fusion of the solder particle.

If the average width of the solder particle is larger than the upper limit of 90%, the excess will prevent the solder particle from adhering to the tacky part or render it readily separable therefrom. If it is smaller than the lower limit of 30%, the shortage will result in adhesion of several solder particles to the opening of the electrode part and deprive the thickness of the solder layer subsequent to the fusion of the solder particle of stability.

This invention prefers the average thickness of the solder particle punched out with the punch to be in the range of 100 to 300% of the thickness of the solder circuit expected to be formed.

The solder metal can be processed into a thin wire because it excels in flatting property as mentioned above. The wire so produced may be cut into definite lengths to produce soldering particles. The wire, either prior to or subsequent to being so cut, may be passed between opposed rollers to produce flat solder particles.

The thickness of the wire under discussion is in the range of 50 to 90%, preferably 55 to 80%, of the width of the electrode part (the inside diameter of the resist opening) and the length of individual particles cut off the line is in the range of 50 to 90%, preferably 55 to 80%, of the width of the electrode part (the inside diameter of the resist opening). When the flat particle is to be produced, the wire prefers to have a width in the range of 30 to 90%, suitably 40 to 80% and more suitably 50 to 70%, of the width of the electrode part.

In adding to the thickness of the solder circuit part in the conventional formation of the solder circuit by the use of a tackiness-imparting compound solution, the method of enlarging the solder particle or the method of increasing the number of treatments has been employed. These methods require imparting tackiness to the circuit part and causing the solder particle to adhere thereto, melting the solder particle, thereby forming a circuit, then imparting tackiness to the circuit, causing the solder particle to adhere to the pertinent portion, and melting the solder particle. The former method tends to add to the mass of the solder particle, heighten the probability of the separation of the solder particle and deprive the thickness of the solder layer of stability. The latter method tends to lower the productivity of the circuit substrate, exert a plurality of thermal hysteresis on the circuit board and consequently deprive the circuit board of reliability.

The method of this invention for producing the solder circuit board prefers to induce the production by placing a solder particle in a solder particle-attaching device, then mounting an electronic circuit board in the device and vibrating the container thereof so as to attach the solder particle to the connecting bump part having consequently acquired tackiness. As a result, the solder particle can be prevented from being scattered.

Even in the method of this invention for the production of the solder circuit board, it is rendered possible to have the solder particles attached to a double-side printed-wiring board by causing the electronic circuit substrate mounted in the solder particle-attaching device to be buoyed from the bottom part of the solder particle-attaching device as by using a jig.

The method of this invention for the production of the solder circuit board prefers to have the solder particle-attaching device to be in the form of a closed container. This scheme renders it possible to prevent the solder particle from being scattered.

This invention particularly prefers the adhesion of the solder particle to the solder circuit board having acquired tackiness in advance to take place in a liquid. By implementing the adhesion of the solder particle in the liquid, it is made possible to prevent the solder particle from adhering to the part lacking tackiness and prevent the solder particle from being aggregated by static electricity and enable use of a fine-pitch circuit board and a very fine solder powder.

This invention prefers the attachment of the solder particle in the liquid to be implemented by fluidizing the solder particle with the current of the liquid. The amount of the solder particles to be supplied in this case is favorably 110% or more of the amount of the solder particles to be attached.

This invention prefers to use water as the liquid necessary for the attachment of the solder particle. For the purpose of preventing the solder particle from being oxidized with the liquid, it is favorable to use a deoxidized liquid or add an antirust to the liquid.

The solder particle-attaching device to be used for the method of producing the solder circuit board contemplated by this invention favorably comprises a container for admitting the solder particle and the electronic circuit board, an inlet port for allowing the electronic circuit board to be injected in a horizontal direction into the container, a mechanism adapted to tilt the container during the insertion of the wiring board into the container and prevent the solder particle from touching the wiring board and a mechanism adapted to tilt or vibrate the container in an opened or closed state. The act of preventing the solder particle from touching the wiring board during the insertion of the wiring board into the container is aimed at avoiding the solder particle from being nipped between the jig and the substrate while the substrate is being set in the solder particle-attaching device and consequently enabling stable setting of the substrate.

While the method of treatment contemplated by this invention can be effectively used particularly for the formation of bumps for the connection of BGA and CSP, it can be naturally applied effectively for the bumps for use in connecting other electronic parts as well.

The solder circuit board that is fabricated according to this invention can be favorably used for a method for mounting an electronic part that comprises the steps of mounting an electronic part and joining the electronic part by reflowing solder. When the solder circuit board fabricated by this invention is expected to make connection of an electronic part, for example, the electronic part can be joined to the circuit board by using a varying method to apply flux to the part of the electronic part requiring connection, mounting the electronic part thereon and then heating the resultant joint, thereby melting the solder and allowing the molten solder to solidify.

As means to connect (mount) the solder circuit board and the electronic part, the surface-mount technology (SMT), for example, may be used. This technology starts with the application of flux to an expected portion of the solder circuit board. It then proceeds to mounting electronic parts, such as the chip part and the QFP, on the bump and effect collective soldering by means of a reflow heat source. As the reflow heat source, a hot blast stove, infrared furnace, vapor condensation soldering device and light beam soldering device are available.

The reflow temperature in the reflow process is +20 to +50° C. relative to the melting point of an alloy to be used, preferably +20 to +30° C. relative to the melting point of the alloy, the preheating temperature is in the range of 130 to 180° C., preferably in the range of 130 to 150° C., the preheating time is in the range of 60 to 120 seconds, preferably in the range of 60 to 90 seconds, and the reflow time is in the range of 30 to 60 seconds, preferably in the range of 30 to 40 seconds.

The reflow process may be carried out in nitrogen or in the air. In the case of nitrogen reflow, by controlling the oxygen concentration to 5 vol. % or less, preferably 0.5 vol. % or less, it is rendered possible to effect the treatment stably because the wettability of the solder to the solder circuit is increased and the occurrence of solder balls is decreased as compared with the case of the air reflow.

Thereafter, the solder circuit board is cooled to complete the surface mounting. In the method for producing the electronic part joint according to this mounting method, the joint may be implemented on both sides of the printed-wiring board. The electronic parts that are usable for the mounting method of this invention for an electronic part include LSI, resistor, capacitor, transformer, inductance, filter, oscillator and transducer besides BGA and CSP connecting chips, for example, though not exclusively.

Now, this invention will be described below by reference to examples, which are not limitative of this invention in any sense.

### Example 1

As the tackiness-imparting compound solution, an aqueous 2 mass % solution of an imidazole-based compound conforming to the general formula (3) by having C₁₁H₂₃ for the alkyl group of R12 and a hydrogen atom for R11 and adjusted with an acetic acid to a pH of about 4 was used. This aqueous solution was heated to 40° C. In the heated aqueous solution, the printed-wiring board pretreated with an aqueous hydrochloric acid solution was immersed for 3 minutes to form a tacky substance on the surface of the copper circuit.

Then, the printed-wiring board was placed in a solder particle-attaching device that was provided with a container whose interior measured 250 mm×120 mm×120 mm and which was provided with an inlet port for admitting the printed-wiring board horizontally thereinto as illustrated in FIG. 1. In the container, water and about 400 g of solder particle having a composition of 96.5Sn-3.5Ag and a particle diameter of 70 μm were placed. During this placement, the solder particle-attaching device was tilted lest the solder particle should touch the wiring board. The wiring board was provided with a connecting bump part opened circularly with a resist of a thickness shown in Table 1 below. Subsequent to placing the wiring board in the solder particle-attaching device, the container was bilaterally tilted by 30° for 10 seconds to induce attachment of the solder particle to the printed-wiring board. The period of tilting was 5 seconds/cycle.

Thereafter, the printed-wiring board was extracted from the device, rinsed gently with pure water and dried.

This printed-wiring board was placed in an oven at 240° C. to melt the solder particle and induce formation of a solder thin film of 96.5Sn-3.5Ag in a thickness of about 20 μm on the exposed surface of the copper circuit. The results are shown in Table 1 below.

TABLE 1

| | Inside | | | (D1 − 2 × ((D2 − | |
|---|---|---|---|---|---|
| | diameter | Solder | Thickness | D3) × D3)^{1/2})/ | Bump |
| | of opening | powder | of resist | D2 | status |
| 1 | 70 μm | 70 μm | 20 μm | 0.1 | Good |
| 2 | 130 μm | 70 μm | 25 μm | 0.9 | Good |
| 3 | 65 μm | 70 μm | 25 μm | −0.03 | Generation of |
| | | | | | unformed part |
| 4 | 135 μm | 70 μm | 20 μm | 1.03 | Large |
| | | | | | variation |
| | | | | | in height |

### Example 2

Squares having a side of 50 μm were punched out of a foil of a solder Cu alloy measuring 50 μm in thickness and containing 3.0% of Sn and 0.5% of Ag. A solder Cu alloy wire measuring 80 μm in diameter and containing 3.0% of Sn and 0.5% of Ag was cut into definite lengths of 50 μm. The two kinds of solder particles thus prepared were put to use herein.

Electronic wiring boards arrayed in the shape of an area having an electrode diameter of 80 μm and an electrode pitch of 180 μm were fabricated. Copper was used for the electrically conductive circuit.

As the tackiness-imparting compound solution, an aqueous 2 mass % solution of an imidazole-based compound conforming to the general formula (3) by having C₁₁H₂₃ for the alkyl group of R12 and a hydrogen atom for R11 and adjusted with an acetic acid to a pH of about 4 was used. This aqueous solution was heated to 40° C. In the heated aqueous solution, the electronic wiring board pretreated with an aqueous hydrochloric acid solution was immersed for 3 minutes to form a tacky substance on the surface of the copper circuit.

Then, the printed-wiring board was placed in a solder particle-attaching device whose interior measured 250 mm×120 mm×120 mm and which was provided with an inlet port for admitting the electronic wiring board horizontally thereinto. In the container, about 10,000 products from the solder foil prepared in Example 1. During this placement, the solder particle-attaching device was tilted lest the solder particle should touch the wiring board. Subsequent to placing the wiring board in the solder particle-attaching device, the container was bilaterally tilted by 30° for 10 seconds to induce attachment of the solder particle to the printed-wiring board. The period of tilting was 5 seconds/cycle.

Thereafter, the electronic circuit board was extracted from the device, rinsed gently with pure water and dried.

This electronic circuit board, after having the whole surface thereof coated with flux, was placed in an oven kept at 240° C. to melt the solder particle and was washed with water to remove the flux. A solder bump was formed in a thickness of about 55 μm on the exposed part of the copper circuit. Incidentally, absolutely no bridge occurred in the solder circuit.

### Example 3

A product of solder (80 μm×50 μm in diameter) produced from a wire was mounted on a varying electrode part having a tacky film formed in advance thereon by the use of a part mounter (part-mounting device). Under the same conditions as in Example 2, the solder was melted to form a solder bump 70 μm in thickness. Incidentally, absolutely no bridge occurred in the solder circuit.

### INDUSTRIAL APPLICABILITY

By the method for producing a solder circuit board that comprises the steps of imparting tackiness to the surface of an electrically conductive circuit board on a printed-wiring board to form a tacky part, attaching a solder particle to the tacky part and melting the solder, thereby forming a solder circuit, it is rendered possible to form a fine solder circuit pattern by the simple procedure and provide a circuit board having the benefit of high reliability. When the solder bump for connecting electronic parts is formed by this method, however, this method entails such problems as suffering a plurality of solder particles to adhere to the tacky part expected to form the bump for the solder circuit board on account of unevenness of the particle diameter of the solder particles, rendering uneven the height of the solder bump, preventing the solder particle from being attached to the expected portion and inducing loss of the solder bump. In contrast, by using a solder particle of a specific particle diameter and allowing just one solder particle to adhere to each opening, it is made possible to cope with a fine circuit pattern, provide a method for producing a solder circuit board free from loss of the solder bump and enable provision of an electronic device having a high integration degree and high reliability as well.

Further, this invention, owing to the use of the product of solder in specific shape and size instead of using a spherical solder particle, has succeeded in enabling production of a solder circuit board excelling in economy, enabling production of a solder circuit board capable of realizing a circuit pattern fine and excellent in processing precision, providing a solder circuit board possessing a circuit pattern fine and excellent in processing precision, scarcely revealing dispersion of solder layer thickness and having the benefit of high reliability, and providing an electronic circuit part having mounted an electronic part capable of realizing high reliability and high packaging density. This invention consequently suppresses short circuits with solder metal between the adjacent circuit patterns even in a fine circuit pattern, acquires an effect of uniformizing the thickness of the circuit pattern, markedly enhances the reliability of the solder circuit board, realizes miniaturization and high reliability of the circuit board having mounted thereon an electronic part, and enables provision of an electronic device having the benefit of excellent properties.

1. A method for producing a solder circuit board, comprising the steps of imparting tackiness to a surface of an electrically conductive circuit electrode on a printed-wiring board to form a tacky part, causing only one solder particle to adhere to the tacky part, and heating the printed-wiring board, thereby melting the solder particle to form a bump part which corresponds to the tacky part and to which an electronic part is to be connected and forming a solder circuit.

2. A method for producing a solder circuit board, comprising the steps of coating part of an electrically conductive circuit electrode on a printed-wiring board with resist so as to form an opening therein, imparting tackiness to the opening to form a tacky part, causing only one solder particle to adhere to the tacky part, and then heating the printed-wiring board, thereby melting the solder particle and forming a solder circuit.

3. A method for producing a solder circuit board according to claim 2, wherein the solder particle is spherical, the opening is circular and, when the opening has a diameter of D1, the solder particle has a diameter of D2 and the resist has a thickness of D3, satisfied is 1>(D1−2×((D2−D3)×D3)^{1/2})/D2≧0.

4. A method for producing a solder circuit board according to claim 1, wherein the solder particle is obtained by punching a solder sheet out.

5. A method for producing a solder circuit board according to claim 4, wherein the solder particle has an average width in a range of 30 to 90% of a size of the opening.

6. A method for producing a solder circuit board according to claim 4, wherein the solder sheet has an average thickness in a range of 100 to 300% of a thickness of the solder circuit to be formed.

7. A method for producing a solder circuit board according to claim 1, wherein the solder particle is a rod of a prescribed length cut from a wire solder.

8. A method for producing a solder circuit board according to claim 7, wherein the wire solder has a thickness in a range of 50 to 90% of a size of the opening.

9. A method for producing a solder circuit board according to claim 1, wherein the step of causing the solder particle to adhere to the tacky part comprises dispersing the solder particle in a liquid and immersing the printed-wiring board in the liquid.

10. A method for producing a solder circuit board according to claim 9, wherein the liquid is a deoxidized liquid.

11. A method for manufacturing a solder circuit board according to claim 1, wherein the solder particle is caused to adhere to the tacky part by means of vibration in an ambient air or by use of an adsorbing jig or mounter.
